(19) United States
(12) Patent Application Publication
(10) Pub. No.: US 2025/0042822 A1
(43) Pub. Date: Feb. 6, 2025

(54) THERMOCHEMICAL TREATMENT FACILITY AND PROCESS FOR MANUFACTURING A COMPOSITE FRICTION COMPONENT

(71) Applicant: SAFRAN CERAMICS, LE HAILLAN (FR)

(72) Inventors: Damien CAZAUBON, MOISSY-CRAMAYEL (FR); Clément Bruno LOMONACO, MOISSY-CRAMAYEL (FR); Adrien DELCAMP, MOISSY-CRAMAYEL (FR)

(21) Appl. No.: 18/720,333

(22) PCT Filed: Dec. 2, 2022
(86) PCT No.: PCT/FR2022/052226

§ 371 Date: Jun. 14, 2024

(30) Foreign Application Priority Data
Dec. 15, 2021 (FR) FR2113563

(51) Int. Cl. C04B 35/83

(52) U.S. Cl. CPC C04B 35/83; C04B 2235/5248; C04B 2235/5252; C04B 2235/614

(57) ABSTRACT

A thermochemical treatment facility includes a reaction chamber and a preheating chamber including a first compartment defining a first gas circulation path between a first gas inlet and the reaction chamber. The preheating chamber further includes at least one second compartment independent of the first compartment defining a second gas circulation path between a second gas inlet and the reaction chamber, the second compartment containing a solid metal or metalloid precursor present in the second gas circulation path.

### TECHNICAL FIELD

The present invention concerns the manufacture of composite material parts and more particularly friction parts based on carbon/carbon (C/C) composite material, such as aircraft brake discs.

### PRIOR ART

Application EP 2,253,604 proposes a process for obtaining a friction part made of carbon/carbon (C/C) composite material incorporating a ceramic phase in the form of grains or crystallites of one or more zirconium compounds. The process disclosed in this application comprises the production of a preform of carbon yarns, densification of the preform by a carbon matrix and, during the manufacturing process, the introduction of ceramic grains or particles dispersed within the part. The friction part obtained by the process described in application EP 2,253,604 exhibits good performance. In return, this process is more complex than the standard process for producing an entirely C/C disk. Indeed, in this application, a first stage of densification by pyrolytic carbon (PyC) is carried out by chemical vapor infiltration (CVI). The part is then discharged from the CVI furnace and immersed in a zirconia precursor sol, dried and heat treated. The part is then introduced again into the CVI furnace, to complete the densification of the PyC matrix. This insertion of zirconium, completely dissociated from the chemical vapor infiltration process, makes manufacturing more time-consuming and complex.

Document EP 0,085,601 discloses a process for manufacturing a composite structure in which Zr—O—C type deposits by CVI are produced using an external chlorinator present upstream of the CVI facility. While this solution has the advantage of being able to process the preform directly in the CVI facility, it has several disadvantages. Zirconium chloride (ZrCl₄) condensation phenomena occur in the pipes connecting the external chlorinator to the CVI facility. To avoid these phenomena, it is necessary to maintain the pipes at a high temperature, which can exceed 600° C., while using valves to ensure the sealing of the circuit. These constraints lead to an increase in the complexity and cost of the technology to be implemented. In addition, the use of an external chlorinator increases the overall size of the facility.

It is therefore desirable to be able to have a solution which makes it possible to produce by CVI deposits of different natures, including at least one deposit of oxide and/or oxycarbide material, without the aforementioned disadvantages.

### DISCLOSURE OF THE INVENTION

According to a first aspect, the present invention relates to a thermochemical treatment facility comprising a reaction chamber and a preheating chamber comprising a first compartment defining a first gas circulation path between a first gas inlet and the reaction chamber, characterized in that the preheating chamber also comprises at least one second compartment, independent of the first compartment, defining a second gas circulation path between a second gas inlet and the reaction chamber, the second compartment containing a metal or metalloid precursor in the solid form present in the second gas circulation path.

By partitioning the preheating chamber in this way, it is possible to deposit oxide and/or oxycarbide into one or more preforms without having to extract them from the reaction chamber. The process for manufacturing a composite material part is thus greatly simplified and the manufacturing time is greatly reduced. Furthermore, in the case of the deposition of a Zr—O—C type phase, the problem of condensation of ZrCl₄ does not arise because the chlorinator is here directly integrated into the preheating chamber, which does not lead to an increase in the overall size of the facility.

According to one embodiment, the metal or metalloid precursor present in the second compartment is a compound or a mixture of compounds chosen from zirconium, titanium, hafnium and yttrium and the second gas inlet is connected to a source of hydrogen dichloride or chloride.

According to a particular aspect, the second compartment comprises a multi-perforated plate supporting the metal or metalloid precursor in solid form.

According to another particular aspect, a layer of quartz wool is interposed between the multi-perforated plate and the metal or metalloid precursor.

According to another embodiment, the first gas inlet is connected to a source of gaseous precursor of pyrolytic carbon.

The invention also has for an object a manufacturing process for a composite material part comprising at least the following steps:
production of at least one fibrous preform made of carbon fibers, or of refractory fibers, or a mixture of carbon fibers and refractory fibers,
loading of the fibrous preform(s) into the reaction chamber of a thermochemical treatment facility according to the invention,
densification of the fibrous preform(s) by a matrix comprising at least a first phase and a second phase, the first matrix phase being formed by chemical vapor infiltration from a first gaseous precursor introduced into the first compartment of the preheating chamber of the thermochemical treatment facility, the second matrix phase being formed by chemical vapor infiltration from a second gaseous precursor obtained by reaction between a reactive gas introduced into the second compartment of the preheating chamber of the thermochemical treatment facility and the metal precursor in solid form present in the second compartment.

The first and second phases described above can be implemented in different orders or sequences. The first phase can be performed before the second phase. The second phase can be performed before the first phase. Each phase can be performed sequentially, i.e., in several steps, by alternating a sequence of forming the first phase with a sequence of forming the second phase. The first and second phases can also be formed simultaneously by the gases passing through the preheating chamber and the gases reacting with the precursor in the reaction chamber.

According to one embodiment, the metal or metalloid precursor present in the second compartment is a compound or a mixture of compounds chosen from zirconium, titanium, hafnium and yttrium and the reactive gas introduced into the second compartment is hydrogen dichloride or chloride.

According to a particular aspect, the second compartment comprises a multi-perforated plate supporting the metal or metalloid precursor in solid form.

According to another particular aspect, a layer of quartz wool is interposed between the multi-perforated plate and the metal or metalloid precursor.

According to one embodiment, the first gaseous precursor is a pyrolytic carbon precursor.

### BRIEF DESCRIPTION OF THE DRAWINGS

FIG. 1 is a schematic sectional view of a thermochemical treatment facility according to one embodiment of the invention.

### DESCRIPTION OF THE EMBODIMENTS

The invention applies to any type of facility or furnace used to carry out heat treatments and in which the gas or gases used in the treatments are preheated in a preheating chamber before their introduction into the reaction chamber or treatment zone of the facility. Such facilities are especially used for carrying out thermochemical densification treatments of porous substrates by chemical vapor infiltration.

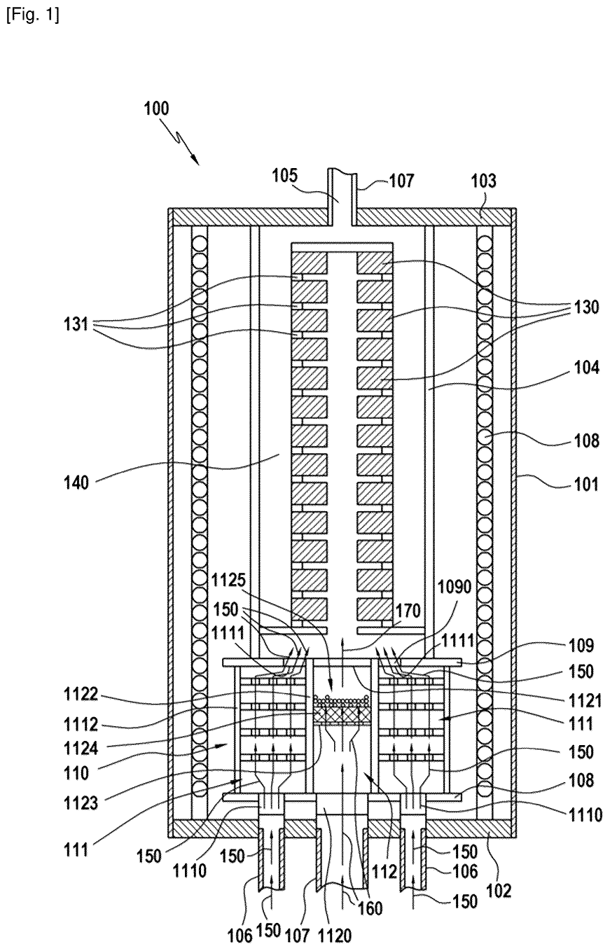

FIG. 1 illustrates a thermochemical treatment facility 100 intended for densification by chemical vapor or gas infiltration (CVI) of fibrous preforms in accordance with an embodiment of the invention. The facility 100 is delimited by a cylindrical side wall 101, a bottom wall 102 and an upper wall 103.

A gas preheating chamber 110, the structure of which will be described in detail below, extends between an inlet plate 108 present in the vicinity of the bottom 102 of the facility and an outlet plate 109 separating the preheating chamber 110 from a loading/treatment zone or reaction chamber 140 delimited by a wall 104. The outlet plate 109 has an opening 1090 enabling the preheating chamber 110 to open into the reaction chamber 140. First and second conduits 106 and 107 present through the bottom 102 respectively connect first and second gas inlets 1110 and 1120 present in the inlet plate 108 of the preheating chamber 110. The upper wall 103 comprises a passage 105 for the evacuation of the effluent gas or gases, the passage 105 being connected by a conduit 107 to suction means, such as a vacuum pump (not shown).

According to the invention, the preheating chamber comprises at least two compartments, each forming independent gas circulation paths. More precisely, in the example described here, a first compartment 111 delimited between a first cylindrical wall 1112 and a second cylindrical wall 1122 extends between the first gas inlet 1110 and a first outlet 1111 emerging at the opening 1090 of the outlet plate 109. The first compartment 111 defines a first gas circulation path between the first gas inlet 1110 and the reaction chamber 140. The preheating chamber further comprises a second compartment 112 delimited by the second cylindrical wall 1122 extending between the second gas inlet 1120 and a second outlet 1121 emerging at the opening 1090 of the outlet plate 109. The second compartment 112 defines a second gas circulation path between the second gas inlet 1120 and the reaction chamber 140.

Still in accordance with the invention, the second compartment 112 contains a metal or metalloid precursor in solid form present in the second gas circulation path which is intended to react with a gas introduced into the second gas inlet 1120. To this end, the second compartment comprises a multi-perforated support plate 1123 interposed in the gas circulation path of the second compartment 112, the plate supporting a solid form, here solid particles 1125 of a metallic or metalloid precursor. According to a particular aspect, a layer of quartz wool 1124 can be interposed between the multi-perforated support plate 1123 and the solid particles 1125. Quartz wool makes it possible to position the solid metal or metalloid precursor in the internal chlorinator, while avoiding contacting it with the support plate. Moreover, it is an inert material that withstands the temperatures encountered in the implementation of the process of the invention.

In the example described here, the facility is heated by induction. More precisely, the cylindrical side wall 104 delimiting the reaction chamber 140 constitutes an armature, or susceptor, for example made of graphite, which is coupled with an inductor 108 located outside the furnace and formed of at least one induction coil. The first cylindrical wall 1112 also constitutes an armature or susceptor, for example made of graphite, which is also coupled with the inductor 108. Optionally, the second cylindrical wall 1122 can also constitute an armature. In a well-known manner, the heating of the reaction chamber 140 and of the preheating chamber 110 is ensured by respectively heating the walls 104 and 1112 when the inductor 108 is supplied with an alternating voltage. For this purpose, the coil or coils of the inductor are connected to an alternating voltage generator (not shown). The magnetic field created by the inductor 108 induces in the walls 104 and 1112 (susceptors) an electric current which causes the walls to be heated by the Joule effect, the elements present inside the reaction chamber 140 and the preheating chamber 110 being heated by radiation.

The facility 100 can be heated by other means such as lamp, microwave, laser ovens, or electrical heating means constituted, for example, by heating resistors embedded in the walls 104 and 1112.

Fibrous preforms 130 to be densified are disposed in the reaction chamber 140. In the example described here, the fibrous preforms 130 correspond to fibrous preforms of brake disks made of carbon yarns and stacked on top of one another, a shim 131 being interposed between two consecutive preforms. However, more generally, the fibrous preforms can be made of carbon fibers, or of refractory fibers (for example SiC), or a mixture of carbon fibers and refractory fibers.

A first gas stream 150, containing a first gaseous precursor of a first phase of a constituent material of the matrix, is admitted into the facility 100 through the first conduit 106 and the first gas inlet 1110. The gas stream is preheated during its circulation in the compartment 111 before it is introduced into the reaction chamber 140.

A second gas stream 160, containing a reactive gas, is admitted into the facility 100 through the second conduit 107 and the second gas inlet 1120. The gas stream 160 circulates in the second compartment, passing through the multi-perforated plate 1123 and the quartz wool layer 1124 in order to reach the solid particles of a metal or metalloid precursor 1125. The gas then reacts with the solid particles in order to form a third gas stream 170 corresponding to a second gaseous precursor of a second phase of a constituent material of the matrix. The gas stream is preheated during its circulation in the compartment 112 before it is introduced into the reaction chamber 140.

The temperature, pressure and flow rates in the facility are adjusted to allow the gas to diffuse into the pores of the fibrous preforms and form a deposit of the matrix materials therein by decomposition of one or more gas constituents; these constituents form the precursor of the matrix. The process is carried out under reduced pressure to promote diffusion of reactive gases into the substrates. The transformation temperature of the precursor or precursors to form the matrix material, such as pyrolytic carbon and/or a ceramic and/or a carbide and/or an oxycarbide, is in most cases comprised between 900° C. and 1100° C.

The first and second phases described above can be implemented in different orders or sequences. The first phase can be performed before the second phase. The second phase can be performed before the first phase. Each phase can be performed sequentially, i.e., in several steps, by alternating a sequence of forming the first phase with a sequence of forming the second phase. The first and second phases can also be formed simultaneously by the gases passing through the preheating chamber and the gases reacting with the precursor in the reaction chamber.

The metal or metalloid precursor present in the second compartment 112 is a compound or a mixture of compounds chosen from at least one of the following compounds: zirconium, titanium, hafnium and yttrium. In the case where the second gas inlet 1120 is connected to a source of hydrogen dichloride or chloride, this makes it possible to form a Zr—O—C, Ti—O—C, Si—O—C, Hf—O—C or Y—O—C phase, or a combination of two or more of these phases in the fibrous preforms 130.

The metal or metalloid precursor is present in the second compartment in solid form, i.e., in the form of particles, powders, grains, sponges, pieces, etc.

An example of a process for manufacturing a composite material part using the thermochemical treatment facility 100 described above will now be described, the process of the invention being used here for manufacturing brake discs made of carbon/carbon (C/C) composite material.

The process begins with the production of annular fibrous preforms, such as the fibrous preforms 130 described above, from precursors of carbon yarns or carbon yarns. Such preforms are made, for example, by superposing layers cut from a fibrous fabric into carbon precursor yarns, bonding the layers together by needle punching and converting the precursor into carbon by heat treatment. In a variant, annular preforms can also be produced by winding a helical fabric of carbon precursor yarns into superposed coils, bonding the coils together by needle punching and transforming the precursor by heat treatment. Reference can be made, for example, to documents U.S. Pat. Nos. 5,792,715, 6,009,605 and 6,363,593. It is also possible to produce the preform directly from layers of fibrous fabric made of carbon yarns which are superposed and bonded together, for example by needling.

Once the fibrous preforms have been produced, they are loaded into the facility 100 and, more precisely, into the reaction chamber 140 as illustrated in FIG. 1.

The solid particles of metal or metalloid precursor 1125 correspond here to solid zirconium particles present in the gas circulation path of the second compartment 112.

The fibrous preforms are then densified by a matrix formed by a first pyrolytic carbon or PyC phase and a second phase of the Zr—O—C type.

According to an exemplary embodiment, densification comprises a first densification cycle in which a first PyC matrix phase is formed by chemical vapor infiltration from a first gaseous precursor (gas stream 150) introduced into the first compartment 111 of the preheating chamber 110 of the facility 100. The first PyC phase can be formed directly on the yarns forming the preform.

After the first densification cycle and before the start of the second densification cycle, a preform partially densified by the first PyC matrix phase is obtained. The first PyC matrix phase can occupy between 5% and 40%, for example between 15% and 25%, of the initial porosity of the fibrous preform.

A second densification cycle is then carried out during which a second matrix phase comprising the Zr—O—C type phase is formed by chemical vapor infiltration from a second gaseous precursor (gas stream 170) obtained by reaction of a chlorine-containing gas (gas stream 160), for example hydrogen dichloride or chloride, with the solid zirconium particles present in the second compartment 112.

The second Zr—O—C matrix phase can be formed directly on the first PyC matrix phase. According to this example, the introduction of the second gaseous precursor into the reaction chamber is initiated during the passage from the first to the second densification cycle.

As a variant, a gaseous mixture of a PyC precursor and the second precursor can be introduced into the reaction chamber during the second densification cycle. In this case, a co-deposition of the Zr—O—C phase and PyC formed by chemical vapor infiltration is obtained.

The second matrix phase can occupy between 1% and 10%, for example between 2% and 7%, of the initial porosity of the fibrous preform.

The gaseous PyC precursor can be chosen from: natural gas, methane, ethane, propane, benzene or a mixture of these compounds.

The matrix formed by CVI from the first and second precursors can occupy at least 50%, or even at least 75%, of the initial porosity of the fibrous preform. A third densification cycle can be carried out, in particular, to complete densification of the preform.

According to a variant, it is possible to co-deposit the first PyC phase and the second Zr—O—C type phase by chemical vapor infiltration. It is thus possible, in particular, to obtain inclusions of Zr—O—C distributed throughout the volume of the matrix. These Zr—O—C inclusions are dispersed in the PyC matrix phase.

The relative proportions between the first PyC precursor and the second Zr—O—C precursor injected determine the mass content of the Zr—O—C phase obtained in the final part. A person skilled in the art knows, by means of their general skills, how to determine the flow rates to be used for the various precursors so as to obtain the desired content for the Zr—O—C phase in the final part. In particular, it is possible to obtain in the final part a mass content of between 0.5% and 25%, or even between 2% and 10%, for the Zr—O—C type phase.

1. A thermochemical treatment facility comprising a reaction chamber and a preheating chamber comprising a first compartment defining a first gas circulation path between a first gas inlet and the reaction chamber, wherein the preheating chamber also comprises at least one second compartment, independent of the first compartment, defining a second gas circulation path between a second gas inlet and the reaction chamber, the second compartment containing a metal or metalloid precursor in the solid form present in the second gas circulation path.

2. The thermochemical treatment facility according to claim 1, wherein the metal or metalloid precursor present in the second compartment is a compound or a mixture of compounds chosen from zirconium, titanium, hafnium and yttrium and the second gas inlet is connected to a source of hydrogen dichloride or chloride.

3. The thermochemical treatment facility according to claim 2, wherein the second compartment comprises a multi-perforated plate supporting the metal or metalloid precursor in solid form.

4. The thermochemical treatment facility according to claim 3, wherein a layer of quartz wool is interposed between the multi-perforated plate and the metal or metalloid precursor.

5. The thermochemical treatment facility according to claim 1, wherein the first gas inlet is connected to a source of gaseous pyrocarbon precursor.

6. A manufacturing process for a composite material part comprising:
production of at least one fibrous preform made of carbon fibers, or of refractory fibers, or a mixture of carbon fibers and refractory fibers
loading of the at least one fibrous preform into the reaction chamber of a thermochemical treatment facility according to claim 1,
densification of the at least one fibrous preform by a matrix comprising at least a first phase and a second phase, the first matrix phase being formed by chemical vapor infiltration from a first gaseous precursor introduced into the first compartment of the preheating chamber of the thermochemical treatment facility, the second matrix phase being formed by chemical vapor infiltration from a second gaseous precursor obtained by reaction between a reactive gas introduced into the second compartment of the preheating chamber of the thermochemical treatment facility and the metal precursor in solid form present in the second compartment.

7. The manufacturing process according to claim 6, wherein the metal or metalloid precursor present in the second compartment is a compound or a mixture of compounds chosen from zirconium, titanium, hafnium and yttrium and the reactive gas introduced into the second compartment is hydrogen dichloride or chloride.

8. The manufacturing process according to claim 7, wherein the second compartment comprises a multi-perforated plate supporting the metal or metalloid precursor in solid form.

9. The manufacturing process according to claim 8, wherein a layer of quartz wool is interposed between the multi-perforated plate and the metal or metalloid precursor.

10. The manufacturing process according to claim 6, wherein the first gaseous precursor is a pyrocarbon precursor.
